(19) United States
(12) Patent Application Publication
(10) Pub. No.: US 2008/0151497 A1
(43) Pub. Date: Jun. 26, 2008

(54) SERVER CABINET WITH AIR EXHAUST APPARATUS

(75) Inventors: HSIU-CHANG LAI, Tu-Cheng (TW); ZHEN-XING YE, Shenzhen (CN); KE SUN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (Shenzhen) CO., LTD., Shenzhen City (CN); HON HAI PRECISION INDUSTRY CO., LTD., Tu-Cheng (TW)

(21) Appl. No.: 11/836,796

(22) Filed: Aug. 10, 2007

(30) Foreign Application Priority Data
Dec. 26, 2006 (CN) 200610201403.8

(51) Int. Cl. H05K 7/20

(52) U.S. Cl. 361/695

(57) ABSTRACT

A server cabinet includes a rack defining an interior space configured for accommodating a plurality of servers therein, and an air exhaust apparatus. The air exhaust apparatus includes a partition board disposed at a back of the interior space of the rack, a blower mounted to the partition board, and an air guiding member secured to the partition board. The partition board defines an opening communicating with the interior space of the rack and an inlet of the blower. The air guiding member has an entrance abutting on an outlet of the blower, and an exit communicating with the outside of the server cabinet.

### BACKGROUND

1. Field of the Invention

The present invention relates to server cabinets, and more particularly to a server cabinet having an air exhaust apparatus.

2. Description of Related Art

Traditionally, for unified management, many servers are arranged in a cabinet. Generally, the cabinet includes a rack that has a plurality of pairs of rails, each pair of rails can support a server.

Due to heat generated by the servers in the cabinet, heated air may accumulate in the cabinet, which may cause failure of the servers in the cabinet. Currently, a plurality of fans is mounted to a top of the cabinet for guiding heated air out of the cabinet. However, cabinets are becoming taller and taller, the fans can only guide the heated air in the upper portion of the cabinet out, while the heated air in the lower portion of the cabinet is seldom guided out. Thus, the servers in the lower portion of the cabinet may be damaged more easily.

What is desired, therefore, is a server cabinet which has an air exhaust apparatus for effectively cooling a plurality of servers in the server cabinet.

### SUMMARY

An exemplary server cabinet includes a rack defining an interior space configured for accommodating a plurality of servers therein, and an air exhaust apparatus. The air exhaust apparatus includes a partition board disposed at a back of the interior space of the rack, a blower mounted to the partition board, and an air guiding member secured to the partition board. The partition board defines an opening communicating with the interior space of the rack and an inlet of the blower. The air guiding member has an entrance abutting on an outlet of the blower, and an exit communicating with the outside of the server cabinet.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a server cabinet in accordance with an embodiment of the present invention, the server cabinet including an air exhaust apparatus;

FIG. 2 is an enlarged view of the air exhaust apparatus of FIG. 1;

FIG. 3 is an assembled view of FIG. 1, with a back plate of the server cabinet being unattached;

FIG. 4 is an assembled view of FIG. 1; and

FIG. 5 is a top view of FIG. 4, and showing the airflow paths in the server cabinet.

### DETAILED DESCRIPTION

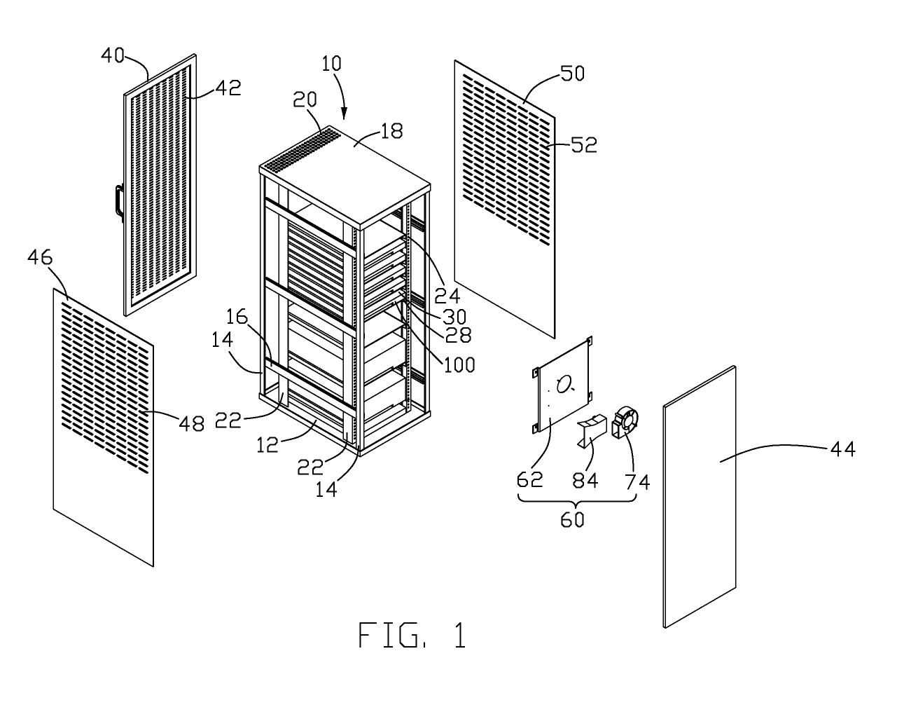

Referring to FIG. 1, in an embodiment of the present invention, a server cabinet includes a rack 10, a front plate 40, a back plate 44, two lateral plates 46, 50, and an air exhaust apparatus 60.

The rack 10 includes a rectangular base 12, a rectangular top cover 18 parallel to the base 12, and four upright members 14 perpendicularly connected between corresponding corners of the base 12 and the top cover 18, thereby defining an interior space for accommodating a plurality of servers 100 therein. A plurality of rib members 16 is horizontally connected between two upright members 14 at each lateral side of the rack 10. A pair of spaced, vertical mounting beams 22 is fastened to inner sides of the rib members 16 at each lateral side of the rack 10. A plurality of linearly arranged retaining orifices 24 is defined in each mounting beam 22. A plurality of spaced, horizontal carrying trays 28 is mounted among the mounting beams 22 from above to below, each to support one of the servers 100 thereon. A channel 30 in a front-and-back direction is formed between every two carrying trays 28 to facilitate air flow therethrough.

A plurality of regularly arrayed venting holes 42, 48, 52, 20 is respectively defined in the front plate 40, the two lateral plates 46, 50, and the top cover 18. The front plate 40, the back plate 44, and the lateral plates 46, 50 are respectively attached to a front side, a back side, and two lateral sides of the rack 10.

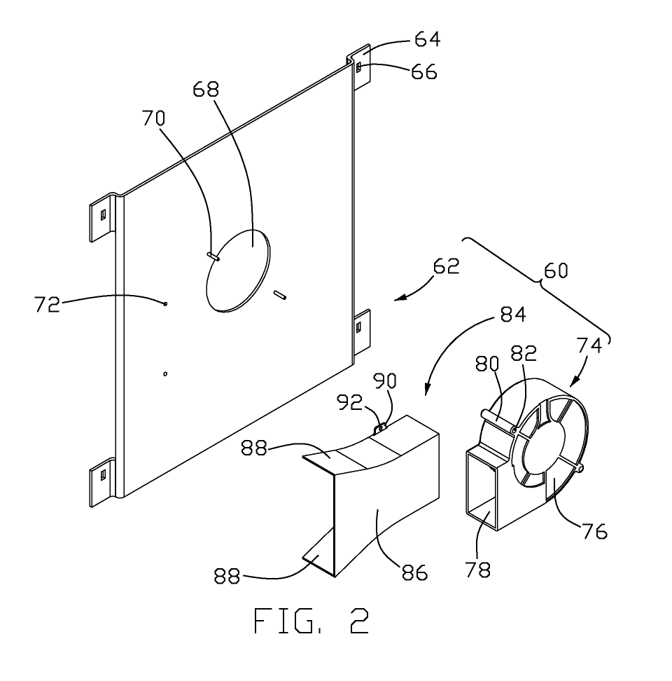

Referring also to FIG. 2, the air exhaust apparatus 60 includes a partition board 62 attached to two mounting beams 22 at the back of the interior space of the rack 10, a blower 74, and an air guiding member 84. The partition board 62 is generally a rectangular metallic plate. Four securing tabs 64 respectively extend out from four corners of the partition board 62. A slot 66 is defined in each securing tab 64. A circular opening 68 is defined in a center of the partition board 62. Two pins 70 perpendicularly protrude from the partition board 62 along a circumference of the opening 68. Two fixing holes 72 are defined in the partition board 62 adjacent a lateral edge thereof. The blower 74 has a housing 76 with an inlet (not visible) defined in a side thereof. An outlet 78 is defined in a scrolled periphery of the housing 76. Two projecting portions 80 are formed on the scrolled periphery of the housing 76. A mounting hole 82 is defined in each projecting portion 80 to allow a corresponding pin 70 of the partition board 62 to insert thereinto. The air guiding member 84 includes a main portion 86 parallel to the partition board 62 and two side portions 88 respectively bent from two sides of the main portion 86 in the same direction. An entrance and an exit are respectively formed at two opposite ends of the air guiding member 84. An area of the entrance is smaller than that of the exit, to facilitate air from the blower 74 quickly flowing out of the air guiding member 84. A fixing tab 90 is perpendicularly extended from an edge of each side portion 88. A coupling hole 92 is defined in each fixing tab 90.

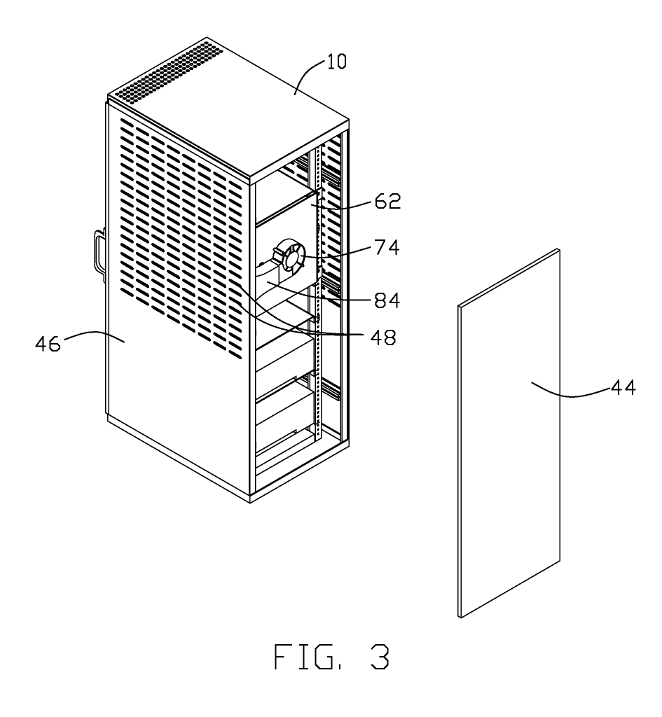

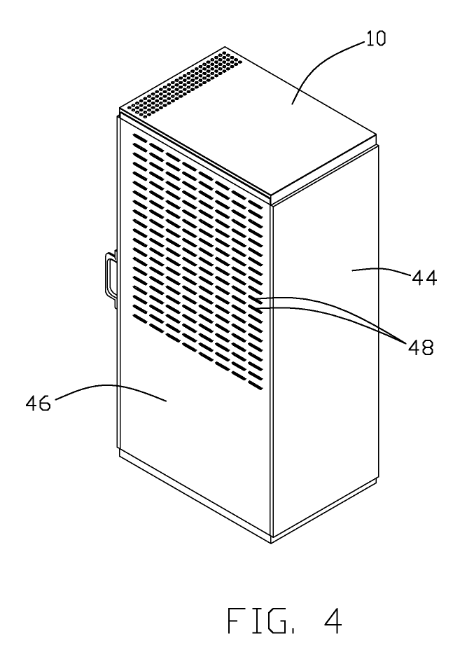

Referring also to FIGS. 3 and 4, in assembly, the partition board 62 is mounted to the two mounting beams 22 at the back of the interior space of the rack 10 via four connecting members (not shown) being passed through the slots 66 of the four securing tabs 64 and engaged in the corresponding retaining orifices 24 of the two mounting beams 22. The opening 68 of the partition board 62 faces the channels 30. The pins 70 of the partition board 62 are interferingly inserted into the corresponding mounting holes 82 of the blower 74 to secure the blower 74 to the partition board 62. The opening 68 of the partition board 62 communicates with the channels 30 and the inlet of the blower 74, to allow the heated air from the servers 100 being drawn into the blower 74 by the blower 74 via the opening 68 and the inlet of the blower 74. The air guiding member 84 is secured to the partition board 62 via two fasteners such as screws (not shown) passing through the coupling holes 92 of the air guiding member 84 and engaging in the corresponding fixing holes 72 of the partition board 62. The entrance of the air guiding member 84 abuts on the outlet 78 of the blower 74, and the exit of the air guiding member 84 communicates with the outside of the server cabinet via the corresponding venting holes 48 of the corresponding lateral plate 46. The back plate 44 is mounted to the back side of the rack 10 and covers the air exhaust apparatus 60.

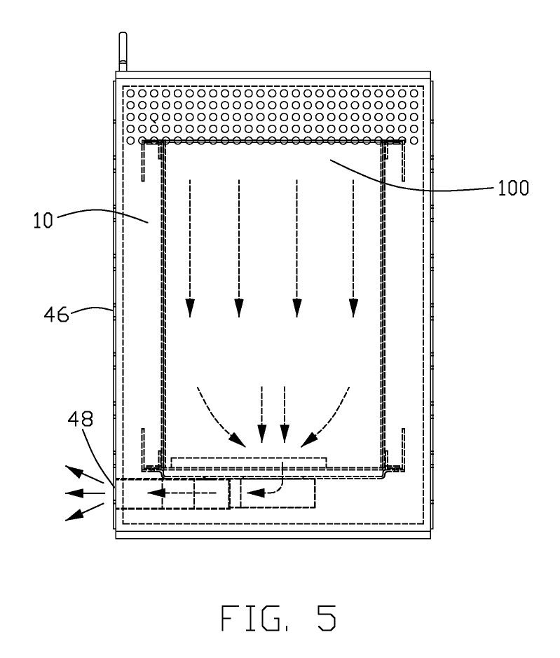

Referring also to FIG. 5, in use, the heated air from the servers 100, as indicated by arrows, is drawn by the blower 74 to enter into the blower 74 through the opening 68 of the partition board 62 and the inlet of the blower 74. The heated air is guided by the air guiding member 84 after being blown out of the blower 74 from the outlet 78, and expelled toward the outside of the server cabinet through the venting holes 48 of the lateral plate 46.

Additionally, the air guiding member 84 may be configured with more than one exit path that extends toward the two lateral plates 46, 50. Thus, the heated air from the servers 100 is expelled toward the outside of the server cabinet through the venting holes 48, 52 of the lateral plates 46, 50. The position of the partition board 62 relative to the rack 10 can be adjustable in an up-and-down direction via the four connecting members engaged in different retaining orifices 24 of the two mounting beams 22 at the back of the interior space of the rack 10.

By virtue of the air exhaust apparatus 60 disposed at the back of the interior space of the rack 100, the heated air from the servers 100 is drawn by the blower 74 from the front to the back of the interior space of the rack 10, and quickly expelled from the server cabinet through the venting holes of the lateral sides of the server cabinet. Thus, airflow paths that the heated air follows are shortened, which effectively improves heat dissipation of the servers 100.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A server cabinet comprising:
a rack defining an interior space configured for accommodating a plurality of servers therein; and
an air exhaust apparatus comprising a partition board disposed at a back of the interior space of the rack, a blower mounted to the partition board, and an air guiding member secured to the partition board, the partition board defining an opening therein for communicating with the interior space of the rack and an inlet of the blower, the air guiding member having an entrance abutting on an outlet of the blower, and an exit communicating with the outside of the server cabinet.

2. The server cabinet as described in claim 1, wherein two pins protrude from the partition board along a circumference of the opening thereof, two mounting holes are defined in the blower, the blower is secured to the partition board via the pins of the partition board being interferingly inserted into the corresponding mounting holes of the blower, respectively.

3. The server cabinet as described in claim 1, wherein two fixing holes are defined in the partition board, two fixing tabs are bent out from the air guiding member, a coupling hole is defined in each of the fixing tabs, the air guiding member is secured to the partition board via two fasteners respectively passing through the coupling holes of the fixing tabs and engaging in the corresponding fixing holes of the partition board.

4. The server cabinet as described in claim 3, wherein the air guiding member includes a main portion and two side portions respectively perpendicularly bent from two sides of the main portion in the same direction, and the fixing tabs are respectively bent out from the two side portions.

5. The server cabinet as described in claim 1, wherein the rack includes a base, a top cover, and four upright members respectively connected between corresponding corners of the base and the top cover.

6. The server cabinet as described in claim 5, wherein two spaced mounting beams stand on the base adjacent each of two opposite lateral sides of the rack, and the partition board is mounted to two mounting beams at the back of the interior space of the rack.

7. The server cabinet as described in claim 6, wherein a plurality of retaining orifices is defined in each of the mounting beams, a plurality of slots is defined in the partition board, and a plurality of connecting members is respectively passed through the slots of the partition board and engaged in the corresponding retaining orifices of the corresponding mounting beams.

8. The server cabinet as described in claim 6, wherein a plurality of spaced carrying trays is mounted among the mounting beams, and each of the carrying trays is configured for supporting one of the servers thereon.

9. A server cabinet comprising:
a rack comprising a base, a plurality of spaced mounting beams standing on the base, and a plurality of spaced carrying trays mounted among the mounting beams and each of the carrying trays configured for supporting a server thereon; and
an air exhaust apparatus comprising a partition board, a blower mounted to the partition board, and an air guiding member secured to the partition board, the partition board being attached to the mounting beams at a back of the rack and extending between an upper carrying tray and a lower carrying tray, the partition board defining an opening therein for communicating with an inlet of the blower, the air guiding member having an entrance abutting on an outlet of the blower, and an exit communicating with the outside of the server cabinet.

10. The server cabinet as described in claim 9, further comprising two lateral plates respectively mounted to two lateral sides of the rack, a plurality of venting holes is defined in at least one lateral plate, and the exit of the air guiding member abuts at an inner surface of said at least one lateral plate, configured for exhausting air through the venting holes.

11. The server cabinet as described in claim 9, wherein a plurality of retaining orifices is defined in each of the mounting beams, a plurality of securing tabs extends out from the partition board, a slot is defined in each of the securing tabs, a plurality of connecting members is respectively passed through the slots of the partition board and engaged in the corresponding retaining orifices of the mounting beams.

12. The server cabinet as described in claim 11, wherein a plurality of pins protrudes from the partition board along a circumference of the opening thereof, a plurality of mounting holes is defined in the blower, the blower is secured to the partition board via the pins of the partition board being interferingly inserted into the corresponding mounting holes of the blower, respectively.

13. The server cabinet as described in claim 11, wherein two fixing holes are defined in the partition board, the air guiding member includes a main portion and two side portions respectively perpendicularly bent from two sides of the main portion in the same direction, two fixing tabs are respectively bent out from the two side portions, a coupling hole is defined in each of the fixing tabs, the air guiding member is secured to the partition board via two fasteners respectively passing through the coupling holes of the air guiding member and engaging in the corresponding fixing holes of the partition board.

14. The server cabinet as described in claim 9, wherein the rack further includes a top cover, four upright members respectively perpendicularly connected between corresponding corners of the base and the top cover, and a plurality of rib members connected between every two upright members at two opposite lateral sides of the rack.

15. A server cabinet comprising:
a rack comprising a plurality of spaced trays configured for supporting servers thereon with a plurality of channels in a front-and-back direction formed therebetween;
a pair of lateral plates respectively mounted to two lateral sides of the rack, one of the lateral plates defining a plurality of venting holes;
a front plate with venting holes mounted to a front side of the rack; and
an air exhaust apparatus comprising a partition board attached to a back side of the rack, a blower mounted to the partition board, and an air guiding member, the partition board defining an opening facing the channels and communicating with the channels and an inlet of the blower such that the blower is capable of drawing heated air from the servers to the back side of the rack via the channels, the air guiding member having an entrance communicating with an outlet of the blower, and an exit communicating with the outside of the server cabinet via the venting holes of the one of the lateral plates.

16. The server cabinet as described in claim 15, further comprising a back plate which is attached to the back side of the rack and covers the air exhaust apparatus.

17. The server cabinet as described in claim 16, further comprising a top cover attached to a top of the rack, wherein a front portion of the top cover defines a plurality of venting holes therein.

18. The server cabinet as described in claim 15, wherein the rack comprises a plurality of mounting beams extending in an up-and-down direction, the trays being attached to and stacked along the mounting beams, the partition board being attached to a pair of the mounting beams located at the back side of the rack.

19. The server cabinet as described in claim 18, wherein said pair of the mounting beams located at the back side of the rack defines a plurality of retaining orifices, and the partition board defines a group of slots configured for a plurality of connecting members extending respectively therethrough to engage in corresponding retaining orifices such that the position of the partition board relative to the rack is adjustable in the up-and-down direction via the connecting members engaging in different retaining orifices.

20. The server cabinet as described in claim 18, wherein the air guiding member is attached to the partition board.
